(19) United States
(12) Patent Application Publication
(10) Pub. No.: US 2015/0200042 A1
(43) Pub. Date: Jul. 16, 2015

(54) RECESSING ULTRA-LOW K DIELECTRIC USING REMOTE PLASMA SOURCE

(71) Applicant: Applied Materials, Inc., Santa Clara, CA (US)

(72) Inventors: Mang Mang Ling, Sunnyvale, CA (US); Sean S. Kang, San Ramon, CA (US); Jeremiah T P Pender, San Jose, CA (US); Srinivas D. Nemani, Sunnyvale, CA (US); Bradley J. Howard, Pleasanton, CA (US)

(73) Assignee: Applied Materials, Inc., Santa Clara, CA (US)

(21) Appl. No.: 14/152,978

(22) Filed: Jan. 10, 2014

(51) Int. Cl. H01B 19/04; H01J 37/32

(52) U.S. Cl. CPC H01B 19/04; H01J 37/32357; H01J 37/3244; H01J 37/32715; H01J 2237/334

(57) ABSTRACT

A portion of the ultra-low k dielectric layer over a substrate is modified using a downstream plasma comprising a first chemistry. The modified portion of the ultra-low k dielectric layer is etched using the downstream plasma comprising a second chemistry. The downstream plasma is generated using a remote plasma source.

### FIELD

Embodiments of the present invention pertain to the field of electronic device manufacturing, and in particular, to ultra-low k (“ULK”) material recessing.

### BACKGROUND

In the semiconductor industry, to achieve performance improvements (e.g., reduction of RC delays, power consumption, cross-talk) for electronic devices of an ever-decreasing size, ULK materials with dielectric constant k close or less than 2.2 may be used.

Generally, back end of line processing to manufacture an electronic device, for example, a multilevel copper interconnect, or other electronic device, involves etching the ULK material. The conventional plasma etching typically uses fluorocarbon based chemistry (e.g., CF₄) that can cause copper erosion. The conventional plasma etching involves ion bombardment of a workpiece comprising the ULK material. The ion bombardment causes damage of the features of the electronic device structure (for example, top corner rounding of the copper line).

Additionally, the feature damage can occur during cleaning of the polymer residue after etching. Further, conventional etching typically results in rough etch front because of polymer micromasking. Conventional wet etching causes an ULK material undercut (for example, beneath the copper line feature), the feature flop-over, and bending.

Current etching techniques do not have the level of control or damage-free nature that is needed for patterning delicate nanometer scale ULK material based structures.

### SUMMARY

Methods and apparatuses to recess an ultra-low k dielectric using a remote plasma source are described.

In one embodiment, a portion of the ultra-low k dielectric layer over a substrate is modified using a downstream plasma comprising a first chemistry. The modified portion of the ultra-low k dielectric layer is etched using the downstream plasma comprising a second chemistry, wherein the downstream plasma is generated using a remote plasma source.

In one embodiment, a portion of the ultra-low k dielectric layer over a substrate is modified using a downstream plasma comprising a first chemistry. The modified portion of the ultra-low k dielectric layer is etched using the downstream plasma comprising a second chemistry, wherein the downstream plasma is supplied using a remote plasma source. The ultra-low k dielectric layer is sublimated to remove by-products of etching.

In one embodiment, a gas comprising a first chemistry is supplied to a remote plasma source. The downstream plasma comprising the first chemistry is generated using the remote plasma source. A portion of the ultra-low k dielectric layer over a substrate is modified using the downstream plasma comprising the first chemistry. A gas comprising a second chemistry is supplied to the remote plasma source. The modified portion of the ultra-low k dielectric layer is etched using the downstream plasma comprising the second chemistry. The downstream plasma comprising the second chemistry is generated using the remote plasma source.

In one embodiment, a portion of the ultra-low k dielectric layer over a substrate is modified using a downstream plasma comprising a first chemistry. The modified portion of the ultra-low k dielectric layer is etched using the downstream plasma comprising a second chemistry, wherein the downstream plasma is generated using a remote plasma source. The first chemistry is argon, helium, other inert gas, nitrogen, hydrogen or any combination thereof.

In one embodiment, a portion of the ultra-low k dielectric layer over a substrate is modified using a downstream plasma comprising a first chemistry. The modified portion of the ultra-low k dielectric layer is etched using the downstream plasma comprising a second chemistry, wherein the downstream plasma is generated using a remote plasma source. The second chemistry is nitrogen fluoride, ammonia, hydrogen, or any combination thereof.

In one embodiment, a portion of the ultra-low k dielectric layer over a substrate is modified using a downstream plasma comprising a first chemistry. The modified portion of the ultra-low k dielectric layer is etched using the downstream plasma comprising a second chemistry, wherein the downstream plasma is generated using a remote plasma source. A first set of parameters is adjusted to control modifying the portion of the ultra-low k dielectric layer over the substrate. The first set of parameters comprises a pressure, a time duration, a power, a temperature, a gas flow, or any combination thereof.

In one embodiment, a portion of the ultra-low k dielectric layer over a substrate is modified using a downstream plasma comprising a first chemistry. The modified portion of the ultra-low k dielectric layer is etched using the downstream plasma comprising a second chemistry, wherein the downstream plasma is generated using a remote plasma source. The downstream plasma is a substantially ion-free plasma. The ultra-low k dielectric layer has a dielectric constant K not greater than 2.2.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching. The modifying is performed at a bias power not greater than 100 W. The modifying, etching and sublimating are continuously repeated until the ultra-low k dielectric layer is etched to a predetermined depth.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching. A protection oxide layer is deposited on the ultra-low k dielectric layer.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching. The first chemistry is argon, helium, other inert gas, nitrogen, hydrogen or any combination thereof.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching. The second chemistry is nitrogen fluoride, ammonia, hydrogen, or any combination thereof.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching. At least one of the modifying and etching is controlled by adjusting a time duration, a power, a pressure, a temperature, a gas flow, or any combination thereof.

In one embodiment, a portion of an ultra-low k dielectric layer between portions of a conductive layer over a substrate is modified using a downstream plasma comprising a first chemistry. The modified portion of the ultra-low k dielectric layer is etched using the downstream plasma comprising a second chemistry. The ultra-low k dielectric layer is sublimated to remove by-products of etching. The sublimating is performed by heating the ultra-low k dielectric layer.

In an embodiment, an apparatus to recess an ultra-low k dielectric layer to manufacture an electronic device comprises a pedestal to hold a workpiece. The workpiece comprises an ultra-low k dielectric layer over a substrate. An inlet to input a gas comprising one of a first chemistry and a second chemistry. A remote plasma source is coupled to the inlet. The remote plasma source comprises a blocker plate to generate a substantially ion-free downstream plasma. The blocker plate is to prevent ions of the plasma to reach the workpiece. A processor is coupled to the remote plasma source. The processor has a first configuration to control modifying a portion of the ultra-low k dielectric layer using the downstream plasma comprising the first chemistry. The processor has a second configuration to control etching of the modified portion of the ultra-low k dielectric layer using the substantially ion-free downstream plasma comprising the second chemistry.

In an embodiment, an apparatus to recess an ultra-low k dielectric layer to manufacture an electronic device comprises a pedestal to hold a workpiece. The workpiece comprises an ultra-low k dielectric layer over a substrate. An inlet to input a gas comprising one of a first chemistry and a second chemistry. A remote plasma source is coupled to the inlet. The remote plasma source comprises a blocker plate to generate a substantially ion-free downstream plasma. The blocker plate is to prevent ions of the plasma to reach the workpiece. A processor is coupled to the remote plasma source. The processor has a first configuration to control modifying a portion of the ultra-low k dielectric layer using the downstream plasma comprising the first chemistry. The processor has a second configuration to control etching of the modified portion of the ultra-low k dielectric layer using the substantially ion-free downstream plasma comprising the second chemistry. The processor has a third configuration to control sublimating the ultra-low k dielectric layer to remove by-products of etching.

In an embodiment, an apparatus to recess an ultra-low k dielectric layer to manufacture an electronic device comprises a pedestal to hold a workpiece. The workpiece comprises an ultra-low k dielectric layer over a substrate. An inlet to input a gas comprising one of a first chemistry and a second chemistry. A remote plasma source is coupled to the inlet. The remote plasma source comprises a blocker plate to generate a substantially ion-free downstream plasma. The blocker plate is to prevent ions of the plasma to reach the workpiece. A processor is coupled to the remote plasma source. The processor has a first configuration to control modifying a portion of the ultra-low k dielectric layer using the downstream plasma comprising the first chemistry. The processor has a second configuration to control etching of the modified portion of the ultra-low k dielectric layer using the substantially ion-free downstream plasma comprising the second chemistry. The processor has a fourth configuration to maintain a bias power less or equal to 100 W. The processor has a fifth configuration to continuously repeat the modifying, etching, and sublimating until the ultra-low k dielectric layer is etched to a predetermined depth.

In an embodiment, an apparatus to recess an ultra-low k dielectric layer to manufacture an electronic device comprises a pedestal to hold a workpiece. The workpiece comprises an ultra-low k dielectric layer over a substrate. An inlet to input a gas comprising one of a first chemistry and a second chemistry. A remote plasma source is coupled to the inlet. The remote plasma source comprises a blocker plate to generate a substantially ion-free downstream plasma. The blocker plate is to prevent ions of the plasma to reach the workpiece. A processor is coupled to the remote plasma source. The processor has a first configuration to control modifying a portion of the ultra-low k dielectric layer using the downstream plasma comprising the first chemistry. The processor has a second configuration to control etching of the modified portion of the ultra-low k dielectric layer using the substantially ion-free downstream plasma comprising the second chemistry. The first chemistry is argon, helium, other inert gas, nitrogen, hydrogen or any combination thereof.

In an embodiment, an apparatus to recess an ultra-low k dielectric layer to manufacture an electronic device comprises a pedestal to hold a workpiece. The workpiece comprises an ultra-low k dielectric layer over a substrate. An inlet to input a gas comprising one of a first chemistry and a second chemistry. A remote plasma source is coupled to the inlet. The remote plasma source comprises a blocker plate to generate a substantially ion-free downstream plasma. The blocker plate is to prevent ions of the plasma to reach the workpiece. A processor is coupled to the remote plasma source. The processor has a first configuration to control modifying a portion of the ultra-low k dielectric layer using the downstream plasma comprising the first chemistry. The processor has a second configuration to control etching of the modified portion of the ultra-low k dielectric layer using the substantially ion-free downstream plasma comprising the second chemistry. The second chemistry is nitrogen fluoride, ammonia, hydrogen, or any combination thereof.

In an embodiment, an apparatus to recess an ultra-low k dielectric layer to manufacture an electronic device comprises a pedestal to hold a workpiece. The workpiece comprises an ultra-low k dielectric layer over a substrate. An inlet to input a gas comprising one of a first chemistry and a second chemistry. A remote plasma source is coupled to the inlet. The remote plasma source comprises a blocker plate to generate a substantially ion-free downstream plasma. The blocker plate is to prevent ions of the plasma to reach the workpiece. A processor is coupled to the remote plasma source. The processor has a first configuration to control modifying a portion of the ultra-low k dielectric layer using the downstream plasma comprising the first chemistry. The processor has a second configuration to control etching of the modified portion of the ultra-low k dielectric layer using the substantially ion-free downstream plasma comprising the second chemistry. A memory is coupled to the processor to store a first set of parameters to control the modifying the portion of the ultra-low k dielectric layer, and to store a second set of parameters to control the etching of the modified portion of the ultra-low k dielectric layer.

Other features of the present invention will be apparent from the accompanying drawings and from the detailed description which follows.

### BRIEF DESCRIPTION OF THE DRAWINGS

The embodiments as described herein are illustrated by way of example and not limitation in the figures of the accompanying drawings in which like references indicate similar elements.

FIG. 1 shows a block diagram of one embodiment of a plasma system to recess an ULK dielectric layer.

FIG. 2A shows a side view of an electronic device structure according to one embodiment.

FIG. 2B is a view similar to FIG. 2A illustrating etching the modified portion of the ultra-low k dielectric layer using the downstream plasma comprising a second chemistry according to one embodiment.

FIG. 2C is a view similar to FIG. 2B illustrating sublimating the ultra-low k dielectric layer to remove by-products of etching according to one embodiment.

FIG. 2D is a view similar to FIG. 2C, after the modifying, etching and sublimating operations are continuously repeated according to one embodiment.

FIG. 2E is a view similar to FIG. 2D, after the modifying, etching and sublimating operations are continuously repeated according to another embodiment.

FIG. 3A shows a side view of an electronic device structure according to one embodiment.

FIG. 3B is a view similar to FIG. 3A illustrating etching the modified portion of the oxide layer with an underlying modified portion of the ultra-low k dielectric layer using the downstream plasma comprising a second chemistry according to one embodiment.

FIG. 3C is a view similar to FIG. 3B illustrating a deposition layer formed after etching the modified portions of the oxide layer and ULK dielectric layer according to one embodiment.

FIG. 3D is a view similar to FIG. 3C illustrating sublimating the ultra-low k dielectric layer to remove the deposition layer according to one embodiment.

FIG. 3E is a view similar to FIG. 3D, after the modifying, etching and sublimating operations are continuously repeated according to one embodiment.

FIG. 4A shows a side view of an electronic device structure according to one embodiment.

FIG. 4B is a view similar to FIG. 4A, showing that the bottom portions of the trenches are selectively modified to a predetermined depth using a downstream plasma 408 comprising a first chemistry according to one embodiment.

FIG. 4C is a view 420 similar to FIG. 4B illustrating etching the modified portion of the ultra-low k dielectric layer 402 using the downstream plasma comprising a second chemistry according to one embodiment.

FIG. 4D is a view 430 similar to FIG. 4C illustrating sublimating 412 of the ultra-low k dielectric layer 402 to remove the by-products 411 according to one embodiment.

FIG. 4E is a view 440 similar to FIG. 4D, after the modifying, etching and sublimating operations are continuously repeated according to one embodiment.

FIG. 5 is a view showing exemplary scanning electronic microscope images illustrating electronic device structures having conductive features on a ULK dielectric material after a modification and after an etching according to one embodiment.

FIG. 6 shows a block diagram of an embodiment of a data processing system to control the plasma system to recess an ULK dielectric as described herein.

### DETAILED DESCRIPTION

In the following description, numerous specific details, such as specific materials, chemistries, dimensions of the elements, etc. are set forth in order to provide thorough understanding of one or more of the embodiments of the present invention. It will be apparent, however, to one of ordinary skill in the art that the one or more embodiments of the present invention may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment of the present invention. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment of this invention. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

Methods and apparatuses to recess an ultra-low k (“ULK”) dielectric using a remote plasma source are described. In one embodiment, a portion of the ULK dielectric layer over a substrate is modified using a downstream plasma comprising a first chemistry. The modified portion of the ULK dielectric layer is etched using the downstream plasma comprising a second chemistry, wherein the downstream plasma is generated using a remote plasma source. The directional etch of the symmetric plasma chamber with the remote plasma source is used to advantageously recess the ULK dielectric without copper damage and ULK material undercut. The symmetric plasma chamber can be one of the C3 chambers (e.g., a Capa chamber) manufactured by Applied Materials, Inc. located in Santa Clara, Calif., or any other symmetric plasma chambers. The remote plasma source can be one of the remote plasma sources (e.g., Siconi source) manufactured by Applied Materials, Inc. located in Santa Clara, Calif., or any other remote plasma source.

In an embodiments, a downstream plasma comprising a first chemistry reduces the bonding between the molecules, polymer chains, or both of the surface portion of the ULK dielectric thereby creating the modified surface portions of the ULK material that can be easily removed by a subsequent etching using substantially ion-free downstream plasma comprising a second chemistry while leaving unmodified portions of the ULK material intact. That is, the modified ULK material and (an optional sidewall protection) are selectively removed by a downstream plasma comprising a second chemistry, as described in further detail below. Because the downstream plasma from the remote plasma source is utilized, the ULK dielectric is advantageously gently recessed without copper erosion, and the top surface of the ULK dielectric that is being recessed is smooth and without residue. The etch profile for ULK dielectric is advantageously vertical and shows no lateral etch, as described in further detail below.

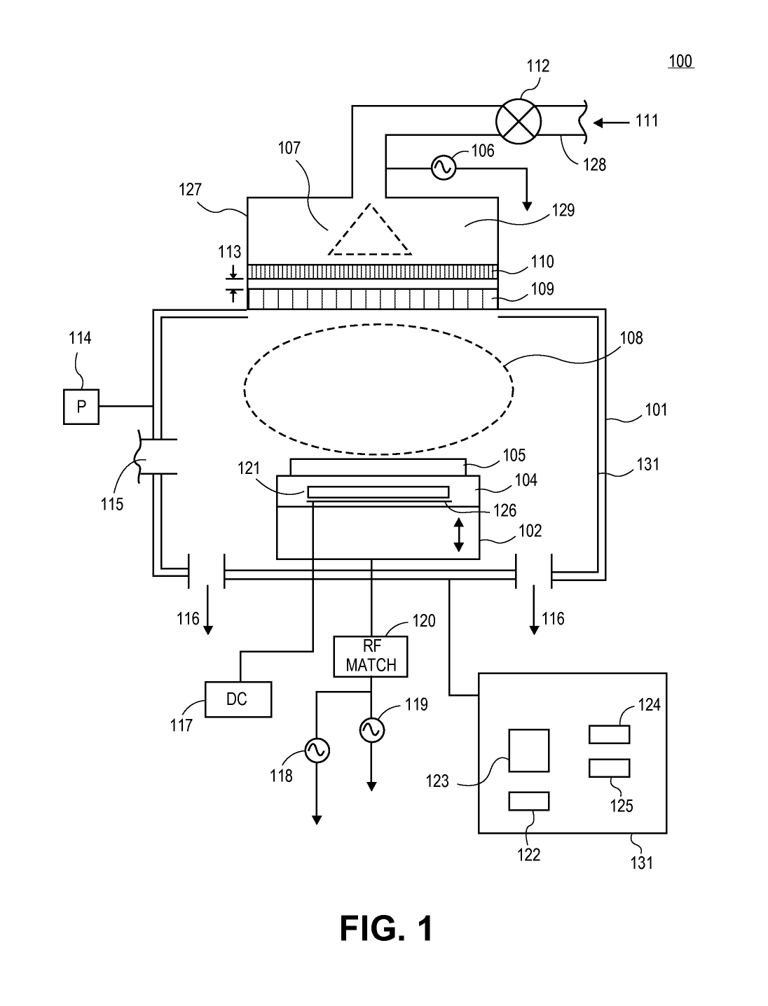

FIG. 1 shows a block diagram of one embodiment of a plasma system 100 to recess an ULK dielectric layer. As shown in FIG. 1, system 100 has a processing chamber 101. In an embodiment, processing chamber 101 is a symmetric plasma chamber. A liner, such as a liner 131 extends along the walls of the chamber 101. A movable pedestal 102 to hold a workpiece 105 is placed in processing chamber 101. Pedestal 102 comprises an electrostatic chuck (“ESC”) 104, a DC electrode 126 embedded into the ESC 104, and a cooling/heating base 121. In an embodiment, pedestal 102 acts as a moving cathode. In an embodiment, the cooling/heating base 121 is an aluminum base, or any other metal base. In an embodiment, ESC 104 comprises an Al₂O₃ material, Y₂O₃, or other ceramic materials known to one of ordinary skill of electronic device manufacturing. In an embodiment, a ceramic puck on the top of the ESC is made from Al₂O₃. A DC power supply 117 is connected to the DC electrode 126.

As shown in FIG. 1A, a workpiece 105 is loaded through an opening 115 and placed on the ESC 104. In an embodiment, the workpiece comprises an ultra-low k dielectric layer over a substrate. The workpiece can be a photomask, a semiconductor wafer, or other workpiece known to one of ordinary skill in the art of electronic device manufacturing. In at least some embodiments, the workpiece comprises any material to make any of integrated circuits, passive (e.g., capacitors, inductors) and active (e.g., transistors, photo detectors, lasers, diodes) microelectronic devices. The workpiece may include insulating (e.g., dielectric) materials that separate such active and passive microelectronic devices from a conducting layer or layers that are formed on top of them. In one embodiment, the workpiece is a semiconductor substrate that includes one or more dielectric layers e.g., silicon dioxide, silicon nitride, sapphire, and other dielectric materials. In one embodiment, the workpiece is a wafer stack including one or more layers. The one or more layers of the workpiece can include conducting, semiconducting, insulating, or any combination thereof layers. System 100 comprises an inlet 128 to input one or more process gases 111.

As shown in FIG. 1, one or more process gases 111 are input through a mass flow controller 112 to a remote plasma source 127. In an embodiment, one or more process gases 111 comprise a chemistry to modify ULK dielectric of the workpiece 105, or a chemistry to etch the modified ULK dielectric of the workpiece 105, as described in further detail below. Remote plasma source 127 is coupled to a RF source power 106. Remote plasma source 127 produces a plasma 107 from one or more process gases 111 using a high frequency electric field. Plasma 107 comprises plasma particles, such as ions, electrons, radicals, or any combination thereof. Remote plasma source 127 comprises a blocker plate 110 over a showerhead 109.

In an embodiment, blocker plate 110 is a conductive (e.g., metal) plate. Blocker plate 110 is separated from showerhead 109 by a gap 113. In an embodiment, plasma 107 is a cone shaped plasma. As shown in FIG. 1, plasma 107 is generated in a remote plasma cavity 129 that is separated from processing chamber 101 by blocker plate 110. The blocker plate 110 prevents ions and electrons of the plasma 107 to reach the processing chamber 101 where workpiece 105 is placed.

As shown in FIG. 1, a substantially ion-free downstream plasma 108 is created based on plasma 107 that pass through blocker plate 110 and showerhead 109 into processing chamber 101. In an embodiment, an amount of ions in plasma 108 to etch the modified ULK dielectric is substantially smaller than the amount of ions in plasma 107, so that the conductive features of the workpiece 103 including the etched ULK dielectric are not damaged by ion bombardment while the anisotropic character of the etching operation is maintained. In an embodiment, power source 106 having frequency about 75 KHz is used to recess the ULK dielectric.

A plasma bias power 119 is coupled to the pedestal 102 (e.g., cathode) via a RF match 120 to energize the plasma. In an embodiment, the plasma bias power 119 has a frequency between about 2 MHz to 60 MHz, and in a particular embodiment, is in the 13.56 MHz band. A plasma bias power 118 may also be provided, for example operating at about 2 MHz to 60 MHz, and in a particular embodiment, is in the 60 MHz band, which is connected to the RF match 120 as plasma bias power 118 to provide a dual frequency bias power. In an embodiment, a total bias power applied to the pedestal 102 is between 10 W and 3000 W. In one embodiment, a total bias power applied to the pedestal 102 is less than or equal to 100 W. In more specific embodiment, a total bias power applied to the pedestal 102 is from about 50 W to about 100 W.

As shown in FIG. 1, a pressure control system 114 provides a pressure to processing chamber 101. As shown in FIG. 1, chamber 101 is evacuated symmetrically via a plurality of symmetrically positioned exhaust outlets 116. The exhaust outlets 116 are connected to a symmetrical vacuum pump system (not depicted) to provide uniformity to evacuate volatile products produced during processing in the chamber.

The symmetric plasma chamber can be one of the C3 chambers (e.g., a Capa chamber) manufactured by Applied Materials, Inc. located in Santa Clara, Calif., or any other symmetric plasma chambers. The remote plasma source can be one of the remote plasma sources (e.g., a Siconi source) manufactured by Applied Materials, Inc. located in Santa Clara, Calif., or any other remote plasma source.

A controller 131 is coupled to the chamber 101. The controller 131 comprises a processor 123, a temperature controller 122 coupled to the processor 123, a memory 124 coupled to the processor 123, and an input/output devices 125 coupled to the processor 123.

In an embodiment, processor 123 has a first configuration to control modifying a portion of the ultra-low k dielectric layer using the downstream plasma comprising a first chemistry. The first chemistry is argon, helium, other inert gas, nitrogen, hydrogen or any combination thereof. The processor 123 has a second configuration to control etching of the modified portion of the ultra-low k dielectric layer using the substantially ion-free downstream plasma comprising a second chemistry. The second chemistry is nitrogen fluoride, ammonia, hydrogen, or any combination thereof, as described in further detail below.

In an embodiment, processor 123 has a third configuration to control sublimating the ultra-low k dielectric layer to remove by-products of etching. The processor 123 has a fourth configuration to maintain a bias power less or equal to 100 W. The processor 123 has a fifth configuration to continuously repeat the modifying, etching, and sublimating until the ultra-low k dielectric layer is etched to a predetermined depth, as described in further detail below. In an embodiment, memory 124 stores a first set of parameters to control modifying of the portion of the ultra-low k dielectric layer, and to store a second set of parameters to control etching of the modified portion of the ultra-low k dielectric layer. The controller 911 is configured to perform methods as described herein and may be either software or hardware or a combination of both.

The system 100 may be any type of high performance semiconductor processing chamber known in the art, such as but not limited to an etcher, a cleaner, a furnace, or any other system to manufacture electronic devices. The system 100 may represent one of the systems manufactured by Applied Materials, Inc. located in Santa Clara, Calif.

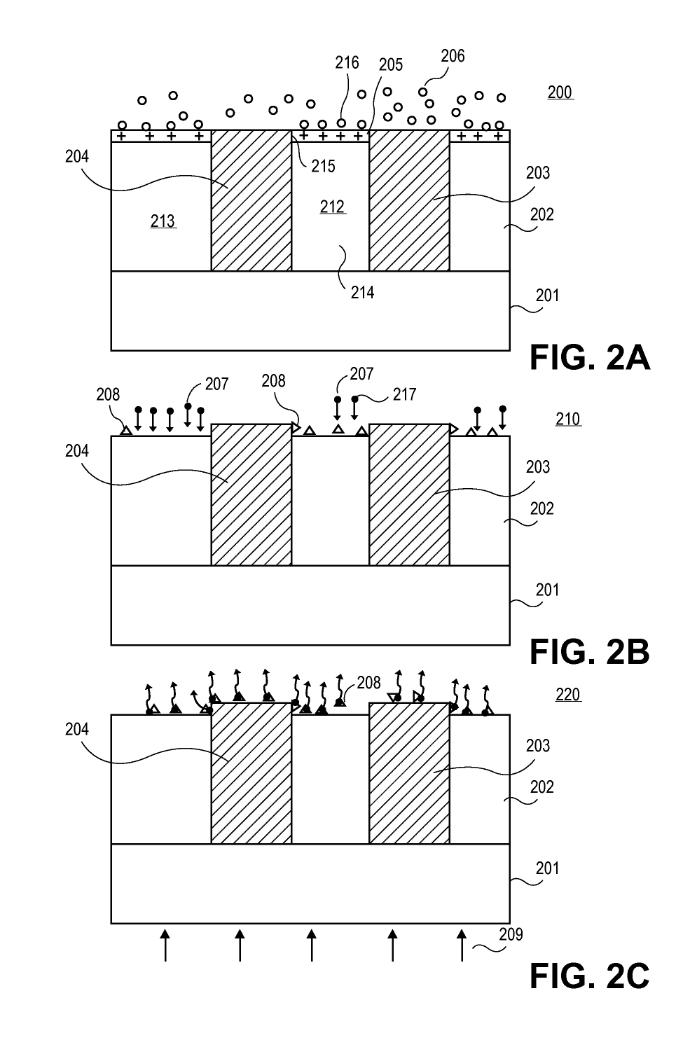

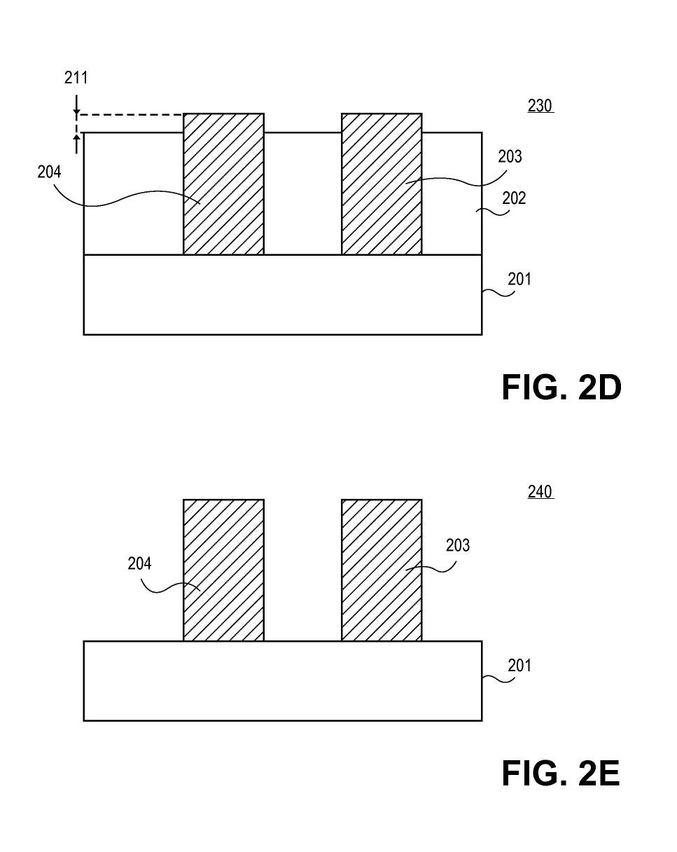

FIG. 2A shows a side view of an electronic device structure 200 according to one embodiment. Electronic device structure 200 comprises an ultra-low k (“ULK”) dielectric layer 202 on a substrate 201. In an embodiment, electronic device structure 200 represents workpiece 105 depicted in FIG. 1. In an embodiment, ULK dielectric layer 202 has dielectric constant K close or less than 2.2. In an embodiment, ULK dielectric layer 202 is a nano-porous SiOC, an aromatic polymer, or any other ULK dielectric layer known to one of ordinary skill in the art of electronic device manufacturing. In an embodiment, ULK dielectric layer 202 is an insulating layer suitable to insulate adjacent devices and prevent leakage. In one embodiment, ULK dielectric layer 202 is an oxide layer, e.g., silicon oxide, or any other electrically insulating layer determined by an electronic device design. In an embodiment, ULK dielectric layer 202 is a silicon oxide (e.g. SiO2) layer, a silicon nitride layer, aluminum oxide (“Al2O3”), silicon oxide nitride (“SiON”), other oxide/nitride layer, any combination thereof, or other electrically insulating layer determined by an electronic device design. In one embodiment, ULK dielectric layer 202 comprises an interlayer dielectric (ILD), e.g., silicon dioxide. In one embodiment, ULK dielectric layer 202 include polyimide, epoxy, photodefinable materials, such as benzocyclobutene (BCB), and WPR-series materials, or spin-on-glass.

A conductive layer 203 is deposited on substrate 201. A conductive layer 203 comprises a plurality of features, such as a feature 204 (e.g., a conductive line, an interconnect, or any other conductive feature known to one of ordinary skill in the art of electronic device manufacturing) between portions 212 and 213 of the ULK layer 202.

In an embodiment, substrate 201 includes a semiconductor material, e.g., monocrystalline silicon (“Si”), germanium (“Ge”), silicon germanium (“SiGe”), a III-V materials based material e.g., gallium arsenide (“GaAs”), or any combination thereof. In one embodiment, substrate 201 includes metallization interconnect layers for integrated circuits. In an embodiment, substrate includes a metallization one (“Ml”) layer.

In one embodiment, substrate 201 includes electronic devices, e.g., transistors, memories, capacitors, resistors, optoelectronic devices, switches, and any other active and passive electronic devices that are separated by an electrically insulating layer, for example, an interlayer dielectric, a trench insulation layer, or any other insulating layer known to one of ordinary skill in the art of the electronic device manufacturing. In at least some embodiments, substrate 201 includes interconnects, for example, vias, configured to connect the metallization layers. In one embodiment, substrate 201 is a semiconductor-on-isolator (SOI) substrate including a bulk lower substrate, a middle insulation layer, and a top monocrystalline layer. The top monocrystalline layer may comprise any material listed above, e.g., silicon.

The features of the conductive layer 203 comprise a metal. In an embodiment, the material for the features of the conductive layer 203 is copper (Cu), aluminum (Al), or a combination thereof. In other embodiments, the material for the conductive features includes aluminum (Al), copper (Cu), indium (In), tin (Sn), lead (Pb), silver (Ag), antimony (Sb), bismuth (Bi), zinc (Zn), cadmium (Cd), gold (Au), ruthenium (Ru), nickel (Ni), cobalt (Co), chromium (Cr), iron (Fe), manganese (Mn), titanium (Ti), hafnium (Hf), tantalum (Ta), tungsten (W), vanadium (V), molybdenum (Mo), palladium (Pd), gold (Au), platinum (Pt), or any combination thereof. In an embodiment, the thickness of the ULK layer 201 is from about 2 nanometers (“nm”) to about 1 micron (μm″). In an embodiment, the thickness of the conductive layer 203 is from about 2 nanometers (“nm”) to about 1 micron (μm″).

As shown in FIG. 2A, a surface portion 205 of the ultra-low k dielectric layer 202 on substrate 202 is selectively modified to a depth 215 using a downstream plasma 206 comprising a first chemistry. As shown in FIG. 2A, the conductive features of the conductive layer 203 remain unmodified by the downstream plasma 206. In an embodiment, the downstream plasma 206 is the substantially ion-free downstream plasma generated using the remote plasma source, as depicted in FIG. 1. In an embodiment, downstream plasma 206 contains radicals of the neutral atoms and/or molecules, such as a radical 216. In an embodiment, an amount of ions in plasma 206 is substantially small, so that the conductive features 204 and the modified surface portion 205 of the ULK dielectric are not damaged by ion bombardment while the anisotropic character of the modification operation is maintained. In an embodiment, the downstream plasma 206 contains the radicals of the atoms and molecules of the first chemistry that is argon, helium, other inert gas, nitrogen, hydrogen or any combination thereof gases. In an embodiment, the surface portion 205 of the ULK layer 202 is modified to a state where it can be chemically removed by a subsequent etching operation, as described in further detail below. In an embodiment, modifying of the surface portion 205 of the ULK layer 202 is controlled by adjusting a set of parameters. In an embodiment, the modification control parameters comprise a pressure, a time duration, a power, a temperature, a gas flow, or any combination thereof. The bonding between the molecules, polymer chains, or both of the modified portions, such as portion 205 is less than that of the rest of the ULK dielectric layer 202, such as a portion 214. In an embodiment, the depth 215 of the modified portion is from about 1 nm to about 4 nm, and more specifically, from about 2 nm to about 3 nm. In another embodiment, the depth of the modified portion is from about 1 nm to about 100 nm.

In an embodiment, the portion of the ULK dielectric is modified by the downstream plasma comprising the first chemistry at a pressure from about 300 mTorr to about 800 mTorr, and more specifically, at about 500 mTorr. In an embodiment, the portion of the ULK dielectric is modified by the downstream plasma comprising the first chemistry for a time duration from about 10 seconds (“sec”) to about 120 sec. In more specific embodiment, the portion of the ULK dielectric is modified by the downstream plasma comprising the first chemistry for a time duration from about 20 sec to about 30 sec.

In an embodiment, the portion of the ULK dielectric is modified by the downstream plasma comprising the first chemistry at a bias power less than or equal to 100 Watts (“W”). In one embodiment, the portion of the ULK dielectric is modified by the downstream plasma comprising the first chemistry at a bias power less than or equal to 100 Watts (“W”). In one embodiment, the portion of the ULK dielectric is modified by the downstream plasma comprising the first chemistry at a bias power from 30 W to about 60 W, and more specifically, at about 50 W.

In an embodiment, the portion of the ULK dielectric is modified by the downstream plasma comprising the first chemistry at a temperature from about 30° C. to about 60° C., and more specifically, at about 50° C.

In an embodiment, a gas flow comprising the first chemistry from about 200 standard cubic centimeters per minute (“sccm”) to about 600 sccm, and more specifically, from about 400 sccm to about 500 sccm is supplied to the remote plasma source to modify the portion of the ULK dielectric.

FIG. 2B is a view 210 similar to FIG. 2A illustrating etching the modified portion of the ultra-low k dielectric layer using the downstream plasma comprising a second chemistry according to one embodiment. As shown in FIG. 2B, a substantially ion-free downstream plasma comprising a second chemistry 207 selectively etches away the modified portions of the ULK dielectric layer 202 along a vertical direction while leaving the conductive features and the unmodified portions of the ULK dielectric layer 202 intact.

In an embodiment, the downstream plasma 207 is the substantially ion-free downstream plasma generated using the remote plasma source, as depicted in FIG. 1. The downstream plasma 207 contains radicals of the neutral atoms and/or molecules, such as a radical 217. In an embodiment, an amount of ions in plasma 207 is substantially small, so that the conductive features 204 and the ULK dielectric are not damaged by ion bombardment while the anisotropic character of the etching operation is maintained. In an embodiment, the downstream plasma 207 contains the radicals of the atoms and molecules of the second chemistry that is nitrogen fluoride, ammonia, hydrogen, or any combination thereof.

In an embodiment, etching of the modified surface portion of the ULK layer 202 is controlled by adjusting a set of parameters. In an embodiment, the modification control parameters comprise a pressure, a time duration, a power, a temperature, a gas flow, or any combination thereof. In an embodiment, the ULK dielectric layer 202 is etched to a depth that corresponds to the depth 215 of the modified portion.

In an embodiment, the modified portion of the ULK dielectric layer is etched by the downstream plasma comprising the second chemistry at a pressure that is greater than the pressure at which the surface portion of the ULK dielectric is modified. In an embodiment, the pressure at which the modified portion of the ULK dielectric layer is etched is from about 2000 mTorr to about 7000 mTorr, and more specifically, at about 5000 mTorr.

In an embodiment, the modified portion of the ULK dielectric is etched by the downstream plasma comprising the second chemistry for a time duration from about 10 sec to about 120 sec. In more specific embodiment, the modified portion of the ULK dielectric is etched by the downstream plasma comprising the second chemistry for a time duration from about 20 sec to about 30 sec. In an embodiment, the modified portion of the ULK dielectric is etched by the downstream plasma comprising the second chemistry at a bias power less than or equal to 100 Watts (“W”). In one embodiment, the modified portion of the ULK dielectric is etched by the downstream plasma comprising the second chemistry at a bias power from 30 W to about 60 W, and more specifically, at about 50 W.

In an embodiment, the modified portion of the ULK dielectric is etched by the downstream plasma comprising the second chemistry at a temperature from about 30° C. to about 60° C., and more specifically, at about 50° C. In an embodiment, decreasing the temperature of the pedestal on which the workpiece is placed, increases the etching rate.

In an embodiment, a gas flow comprising the second chemistry from about 10 sccm to about 2000 sccm, and more specifically, from about 20 sccm to about 1000 sccm is supplied to the remote plasma source to etch the modified portion of the ULK dielectric. In an embodiment, increasing the gas flow rate of the second chemistry increases the etching rate of the modified portion of the ULK dielectric.

In an embodiment, one or more parameters of the modifying operation are adjusted to control etching of the modified portion of the ULK dielectric layer. In an embodiment, increasing the modification time increases the amount of the removed ULK material. In an embodiment, increasing the modification gas flow rate increases etching rate of the modified portion of the ULK dielectric layer.

In an embodiment, the modification chemistry (first chemistry) affects the etching operation as well as surface roughness. In an embodiment, modifying the ULK material using nitrogen provides less surface roughness.

In an embodiment, one or more parameters of the modifying and etching operations are adjusted to minimize roughness and residues, and maximize uniformity of etching. In an embodiment, the uniformity of the etched ULK dielectric layer along the semiconductor wafer having the size of about 300 mm is about +/−2 nm. As shown in FIG. 2B, etching of the modified portion of the ULK layer 202 produces by-products 208 (e.g., salts) that reside on the ULK dielectric layer 202 and conductive features of the conductive layer 202.

FIG. 2C is a view 220 similar to FIG. 2B illustrating sublimating the ultra-low k dielectric layer to remove by-products of etching according to one embodiment. Generally, the etching rate of the ULK material is a function of the transport of reactants to the surface of the ULK material, adsorption of the reactants on the surface of the ULK material; diffusion through byproducts on the surface of the ULK material, chemical reaction rate, and desorption of the byproducts from ULK material. At high wafer temperature, etching is limited by net flux: adsorption—desorption. Surface modification promotes adsorption and enhances etch rate.

In an embodiment, the sublimation involves heating 209 of the ultra-low k dielectric layer. In an embodiment, the by-products 208 are removed by heating the ULK dielectric layer 202. In an embodiment, the temperature of the ULK layer 202 is increased by increasing the temperature of the heating element embedded in the ESC, as depicted in FIG. 1. In an embodiment, the by-products 208 are removed from the etched ULK layer 202 by heating the etched ULK dielectric 202 at the temperature from about 80° C. to about 150° C., and more specifically, at about 110° C. for a time duration of at least 60 sec. In an embodiment, a sequence of the modifying, etching and sublimating operations is continuously repeated until the ultra-low k dielectric layer 202 has been etched to a predetermined depth. In another embodiment, a sequence of the modifying, etching and sublimating operations is continuously repeated until the ultra-low k dielectric layer 202 is completely etched away from substrate 201.

FIG. 2D is a view 230 similar to FIG. 2C, after the modifying, etching and sublimating operations are continuously repeated according to one embodiment. As shown in FIG. 2D, the modifying, etching and sublimating operations are continuously repeated until the ultra-low k dielectric layer 203 has been etched to a predetermined depth 211. As shown in FIG. 2D, the conductive features 204 and the ULK layer 202 are free of the etching by-products, top corner rounding, and undercut.

FIG. 2E is a view 240 similar to FIG. 2D, after the modifying, etching and sublimating operations are continuously repeated according to another embodiment. As shown in FIG. 2E, the modifying, etching and sublimating operations are continuously repeated until the ultra-low k dielectric layer 202 is completely etched away from substrate 201. As shown in FIG. 2E, the conductive features 204 and the substrate 201 are free of the etching by-products, top corner rounding, and undercut.

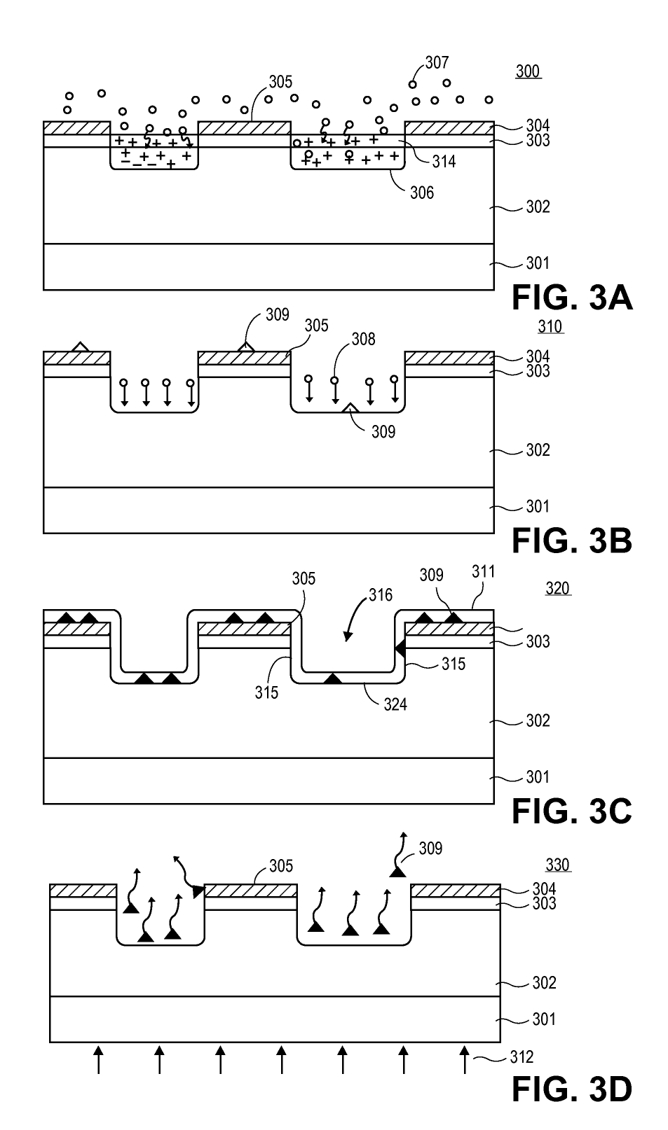

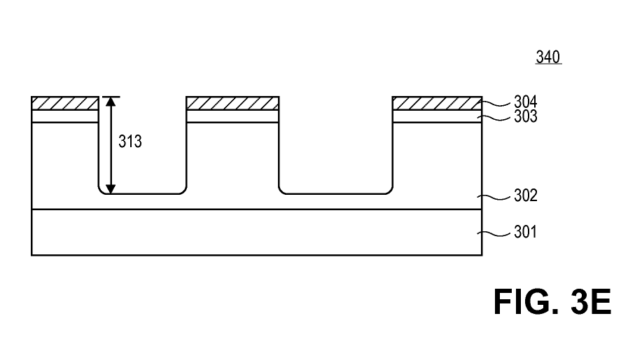

FIG. 3A shows a side view of an electronic device structure 300 according to one embodiment. Electronic device structure 300 comprises an ultra-low k (“ULK”) dielectric layer 302 on a substrate 301. In an embodiment, electronic device structure 300 represents workpiece 105 depicted in FIG. 1. In an embodiment, ULK dielectric layer is one of the ULK dielectric layers described above. An oxide layer 303 is deposited on ULK dielectric layer 302. In an embodiment, oxide layer 303 is silicon oxide (e.g., SiO₂, SiO), silicon oxide nitride, aluminum oxide, or any other oxide layer determined by an electronic design, as known to one of ordinary skill in the electronic device manufacturing. An oxide layer 303 can be deposited using one of a deposition techniques, such as but not limited to a chemical vapour deposition (“CVD”), e.g., a Plasma Enhanced Chemical Vapour Deposition (“PECVD”), a physical vapour deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing. In an embodiment, the thickness of the oxide layer 303 is from about 1 nm to about 50 nm. A patterned conductive layer 304 is deposited on oxide layer 303. A conductive layer 304 comprises a plurality of features, such as a feature 305 (e.g., a conductive line, an interconnect, or any other conductive feature known to one of ordinary skill in the art of electronic device manufacturing). Conductive layer 304 represents one of the conductive layers described above.

In an embodiment, substrate 301 represents one of the substrates described above. As shown in FIG. 3A, a surface portion 306 of the ultra-low k dielectric layer 302 is selectively modified through a portion 314 of the oxide layer 303 not covered by conductive layer 304 to a predetermined depth using a downstream plasma 307 comprising a first chemistry. As shown in FIG. 3A, the conductive features 305 with the underlying portions of the conductive layer 304 remain unmodified by the downstream plasma 307. In an embodiment, downstream plasma 307 represents one of the downstream plasmas comprising the chemistry to modify the portions of the ULK layer described above. In an embodiment, modifying of the surface portions 306 of the ULK layer 302 is controlled by adjusting a set of parameters. In an embodiment, the modification control parameters comprise a pressure, a time duration, a power, a temperature, a gas flow, or any combination thereof, as described above. The bonding between the molecules, polymer chains, or both of the modified portions 306 is less than that of the rest of the ULK dielectric layer 302, as described above. In an embodiment, the depth of the modified portion 306 is from about 1 nm to about 4 nm, and more specifically, from about 2 nm to about 3 nm. In another embodiment, the depth of the modified portion 306 is from about 1 nm to about 100 nm, as described above.

FIG. 3B is a view 310 similar to FIG. 3A illustrating etching the modified portion of the oxide layer 303 with an underlying modified portion of the ultra-low k dielectric layer 302 using the downstream plasma comprising a second chemistry according to one embodiment. As shown in FIG. 3B, a substantially ion-free downstream plasma comprising a second chemistry 308 selectively etches away the modified portions of the oxide layer 303 and the ULK dielectric layer 302 along a vertical direction while leaving the conductive features and the unmodified portions of the oxide layer 303 and the ULK dielectric layer 302 intact.

In an embodiment, the downstream plasma 308 represents one of the downstream plasmas comprising the chemistry to etch the modified portions the ULK dielectric layer described above. In an embodiment, etching of the modified portion of the oxide layer 303 and the ULK layer 303 is controlled by adjusting a set of parameters, as described above. In an embodiment, the modification control parameters comprise a pressure, a time duration, a power, a temperature, a gas flow, or any combination thereof, as described above. In an embodiment, the ULK dielectric layer 302 is etched to a depth that corresponds to the depth of the modified portion 306. As shown in FIG. 3B, etching of the modified portions of the oxide layer 303 and ULK layer 302 produces by-products 309 (e.g., silicon based depositions, salts) that are deposited on the ULK dielectric layer 302 and conductive features of the conductive layer 302.

FIG. 3C is a view 320 similar to FIG. 3B illustrating a deposition layer 311 formed after etching the modified portions of the oxide layer and ULK dielectric layer according to one embodiment. As shown in FIG. 3C, deposition layer 311 comprising by-products 309 is formed on the features 305 of the conductive layer 304, on a bottom 324 and sidewalls 315 of a trench 316 etched in the ULK dielectric layer 302. In an embodiment, the thickness of the silicon-based deposition layer 311 is less than 10 nm.

FIG. 3D is a view 330 similar to FIG. 3C illustrating sublimating the ultra-low k dielectric layer 302 to remove the deposition layer 311 according to one embodiment.

In an embodiment, the sublimation involves heating 312 of the ultra-low k dielectric layer 302 on substrate 301, as described above. In an embodiment, the deposition layer 311 comprising by-products 309 is removed from the conductive layer, oxide layer 303, and ULK layer 302 by heating 312, as described above. In an embodiment, a sequence of the modifying, etching and sublimating operations is continuously repeated until the portions of the ultra-low k dielectric layer 302 exposed by conductive layer 304 have been etched to a predetermined depth. In another embodiment, a sequence of the modifying, etching and sublimating operations is continuously repeated until the exposed portions of the ultra-low k dielectric layer 302 are completely etched away from substrate 302, as described above.

FIG. 3E is a view 340 similar to FIG. 3D, after the modifying, etching and sublimating operations are continuously repeated according to one embodiment. As shown in FIG. 3E, the modifying, etching and sublimating operations are continuously repeated until the ultra-low k dielectric layer 302 has been etched to a predetermined depth 313. As shown in FIG. 3E, the conductive features of the conductive layer 304 the oxide layer 303, and the ULK layer 202 are free of the etching by-products, top corner rounding, and undercut.

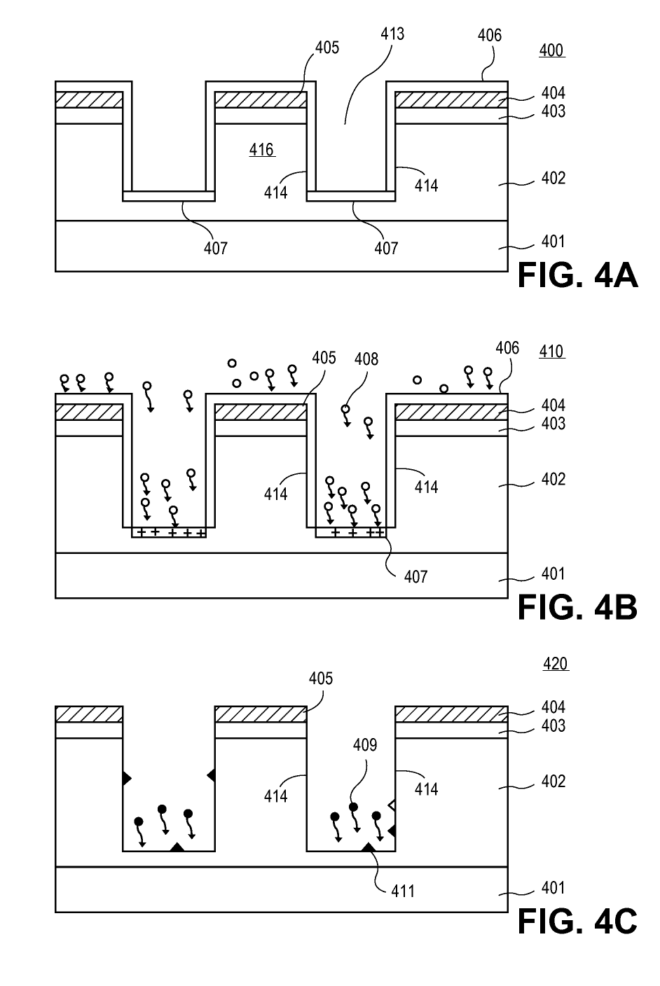

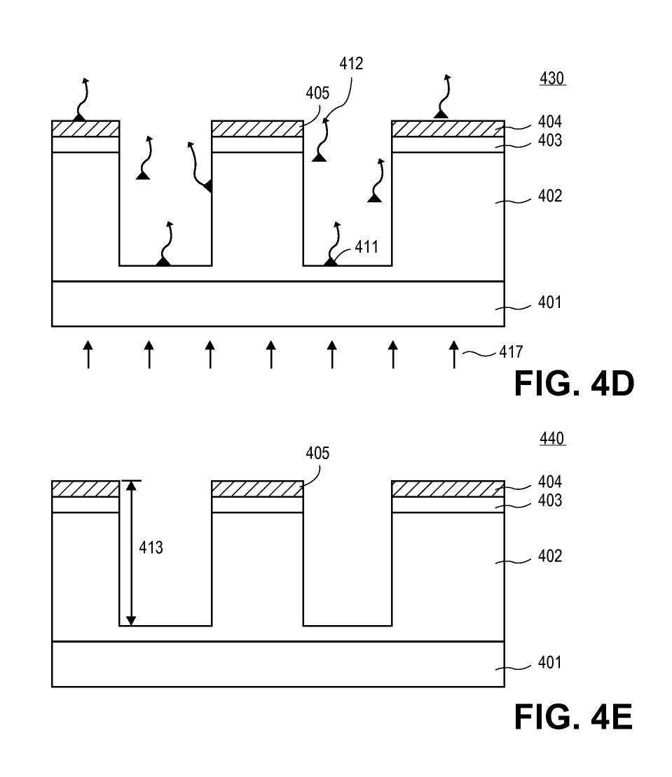

FIG. 4A shows a side view of an electronic device structure 400 according to one embodiment. Electronic device structure 400 comprises an ultra-low k (“ULK”) dielectric layer 402 on a substrate 401. In an embodiment, electronic device structure 400 represents workpiece 105 depicted in FIG. 1. In an embodiment, ULK dielectric layer is one of the ULK dielectric layers described above. ULK dielectric layer 402 comprises trenches, such as a trench 413 and fins, such as a fin 416. Trench 413 has a bottom portion 407 and sidewalls 414. A conductive layer 404 comprising a plurality of features, such as a feature 405 is deposited over the fins of the ULK dielectric layer 402. The conductive layer 404 represents one of the conductive layers described above. An oxide layer 403 is deposited on the fins of the ULK dielectric layer 402 underneath the features of the conductive layer 404. Oxide layer 403 represents one of the oxide layers described above.

In an embodiment, substrate 401 represents one of the substrates described above. As shown in FIG. 3A, a protection layer 406 is deposited on the conductive layer 403 and sidewalls 414 of the ULK dielectric layer 402. In an embodiment, protection layer 406 is a thin oxide layer deposed in-situ for sidewall protection. In an embodiment, protection layer 406 is removed simultaneously with the modified portion of the ULK film at a sublimation operation later in a process. In an embodiment, protection layer 406 is trimethylsilane based oxide (e.g., “TMS/O₂”), or other oxide layer. In an embodiment, protection layer 406 is deposited in-situ by supplying deposition chemistry oxygen containing gases into the plasma chamber using a Plasma Enhanced Chemical Vapour Deposition (“PECVD”) technique. In other embodiments, protection layer 406 is deposited using other deposition techniques, such as but not limited to a chemical vapour deposition (“CVD”), e.g., a physical vapour deposition (“PVD”), molecular beam epitaxy (“MBE”), metalorganic chemical vapor deposition (“MOCVD”), atomic layer deposition (“ALD”), or other deposition techniques known to one of ordinary skill in the art of electronic device manufacturing. In an embodiment, the thickness of the protection layer 403 is from about 2 nm to about 50 nm.

FIG. 4B is a view 410 similar to FIG. 4A, showing that the bottom portions 407 of the trenches, such as bottom portion 407 of the ultra-low k dielectric layer 413 are selectively modified to a predetermined depth using a downstream plasma 408 comprising a first chemistry according to one embodiment. As shown in FIG. 4B, the conductive features 405 and the sidewalls of the underlying portions of the ULK dielectric 402 and oxide layer 403 remain unmodified by the downstream plasma 408. In an embodiment, downstream plasma 408 represents one of the downstream plasmas comprising the chemistry to modify the portions of the ULK layer described above. In an embodiment, modifying of the bottom portions of the trenches in the ULK layer 402 is controlled by adjusting a set of parameters. In an embodiment, the modification control parameters comprise a pressure, a time duration, a power, a temperature, a gas flow, or any combination thereof, as described above. The bonding between the molecules, polymer chains, or both of the modified portion 407 is less than that of the rest of the ULK dielectric layer 402, as described above. In an embodiment, the depth of the modified portion 407 is from about 1 nm to about 4 nm, and more specifically, from about 2 nm to about 3 nm. In another embodiment, the depth of the modified portion 407 is from about 1 nm to about 100 nm, as described above.

FIG. 4C is a view 420 similar to FIG. 4B illustrating etching the modified portion of the ultra-low k dielectric layer 402 using the downstream plasma comprising a second chemistry according to one embodiment. As shown in FIG. 4C, a substantially ion-free downstream plasma comprising a second chemistry 409 selectively etches away the modified portions of the ULK dielectric layer 402 along a vertical direction. As shown in FIG. 4C, protection layer 406 is etched away using a substantially ion-free downstream plasma comprising a second chemistry 409. As shown in FIG. 4C, the conductive features and the sidewalls 414 of the trench in the ULK dielectric layer 402 remain intact by this etching operation.

In an embodiment, the downstream plasma 409 represents one of the downstream plasmas comprising the chemistry to etch the modified portions the ULK dielectric layer described above. In an embodiment, etching of the modified portion of the ULK layer 402 is controlled by adjusting a set of parameters, as described above. In an embodiment, the modification control parameters comprise a pressure, a time duration, a power, a temperature, a gas flow, or any combination thereof, as described above. In an embodiment, the ULK dielectric layer 402 is etched to a depth that corresponds to the depth of the modified portion 407. As shown in FIG. 4C, etching of the modified portions of the ULK layer 402 produces by-products 411 (e.g., silicon based depositions, salts) on the ULK dielectric layer 402 and conductive features of the conductive layer 404.

FIG. 4D is a view 430 similar to FIG. 4C illustrating sublimating 412 of the ultra-low k dielectric layer 402 to remove the by-products 411 according to one embodiment. In an embodiment, the sublimation involves heating 417 of the ultra-low k dielectric layer 402, as described above.

In an embodiment, a sequence of the modifying, etching and sublimating operations is continuously repeated until the portions of the ultra-low k dielectric layer 402 exposed by conductive layer 304 have been etched to a predetermined depth. In another embodiment, a sequence of the modifying, etching and sublimating operations is continuously repeated until the exposed portions of the ultra-low k dielectric layer 402 are completely etched away from substrate 302, as described above.

FIG. 4E is a view 440 similar to FIG. 4D, after the modifying, etching and sublimating operations are continuously repeated according to one embodiment. As shown in FIG. 4E, the modifying, etching and sublimating operations are continuously repeated until the ultra-low k dielectric layer 402 has been etched to a predetermined depth 413. As shown in FIG. 4E, the conductive features of the conductive layer 404 the oxide layer 403, and the ULK layer 402 are free of the etching by-products, top corner rounding, and undercut.

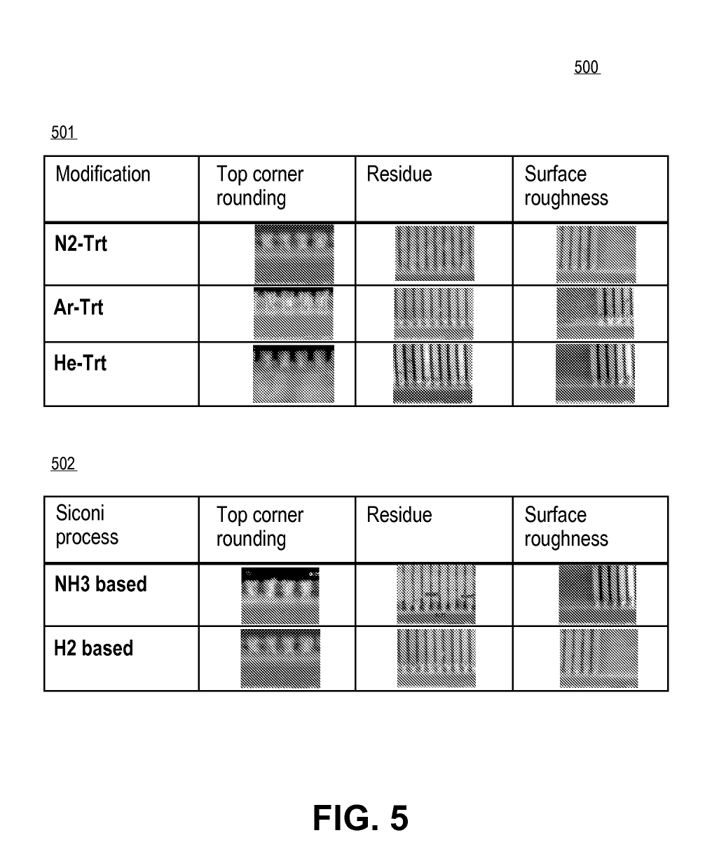

FIG. 5 is a view 500 showing exemplary scanning electronic microscope (“SEM”) images illustrating electronic device structures having conductive features on a ULK dielectric material after a modification 501 and after an etching 502 according to one embodiment. As shown in image 501 of FIG. 5, the electronic device structures after modification of the ULK dielectric using nitrogen (N2), argon (Ar), and helium (He) have substantially reduced surface roughness and are substantially free of the top corner rounding, residue, and undercut. As shown in image 502 of FIG. 5, the electronic device structures after etching of the ULK dielectric using NH₃, H₂ based chemistries have substantially reduced surface roughness and are substantially free of the top corner rounding, residue, and undercut.

As known to one of ordinary skill in the art, the etch of the ULK material caused by the chemical reaction between the reactive species of the plasma and the ULK material surface initiated by ion or electron bombardment is directional. Typically, the etch profile of the masked ULK layer generated by the directional etch is anisotropic without undercut. Contrary to the directional etch, the etch profile generated by undirectional etch is isotropic, with undercut.

In an embodiment, a symmetrical plasma etch tool (e.g., a Capa chamber)) that has excellent directional etch capability is used for recessing the ULK dielectric. In an embodiment, recessing the ULK dielectric involving pre-treatment (modification) of the ULK material surface using nitrogen, helium or argon with properly adjusted bias power, pressure and gas flow, followed by Siconi etching process using NF3, NH3, or a both NF3 and NH3 based chemistries at a proper temperature (e.g., about 50° C.) removes the ULK to a target depth without lateral loss and undercut of the ULK material around the copper line feature.

In an embodiment, use of the symmetric plasma chamber body (e.g., C3 chamber body) and a remote plasma source (e.g., Siconi source) to etch the ULK material provides an advantage of removing the ULK material without copper damage and the ULK material undercut underneath the copper line. The resulting etch profile for the ULK material etched using methods described herein is vertical and shows no lateral etch, as shown in FIG. 5. The reason is that the use of the symmetric plasma chamber body (e.g., C3 chamber body) and a remote plasma source (e.g., Siconi source) is remote plasma assisted dry etch process which involves exposure of the ULK material to NF3/NH3 or NF3/H2 plasma by-products. Remote plasma excitation of the hydrogen and fluorine species advantageously allows plasma-damage-free ULK dielectric processing. The Siconi process produces salts which grow on the surface of the ULK dielectric substrate as the ULK dielectric is removed.

In an embodiment, the balance between absorption and desorption of the etchant is important for the ULK material removal process. The solid by-products are subsequently removed via sublimation when the temperature of the substrate is raised to as high as 110° C. degree. Process parameter such as ESC temperature, Siconi pressure, NF3/NH3 or NF3/H2 gas ratio and total gas flow are adjusted to reduce etch residue. Comparing with existing techniques, embodiments described herein advantageously achieve higher ULK material etch rate, smoother ULK etch surface, no top corner rounding of copper line features, and no ULK undercut underneath the copper lines. The ULK center/edge etch uniformity can also be achieved using methods described herein. In an embodiment, the modification chemistry (e.g., nitrogen, helium, argon gases), modification time, bias power for the modification of the ULK dielectic control ULK dielectric etch rate, surface roughness for the ULK dielectric etch, top corner rounding of copper. In an embodiment, the total flow of NF3/NH3 or NF3/H2 chemistry for the etching process with the remote plasma source controls the surface residue for ULK etch performance. Methods and apparatuses described herein can be used for back-end-of-line (BEOL) barrier etch, logic contact etch, front-end-of-line (FEOL) self-aligned contact (SAC) etch, nitride spacer etch and for other electronic device manufacturing applications.

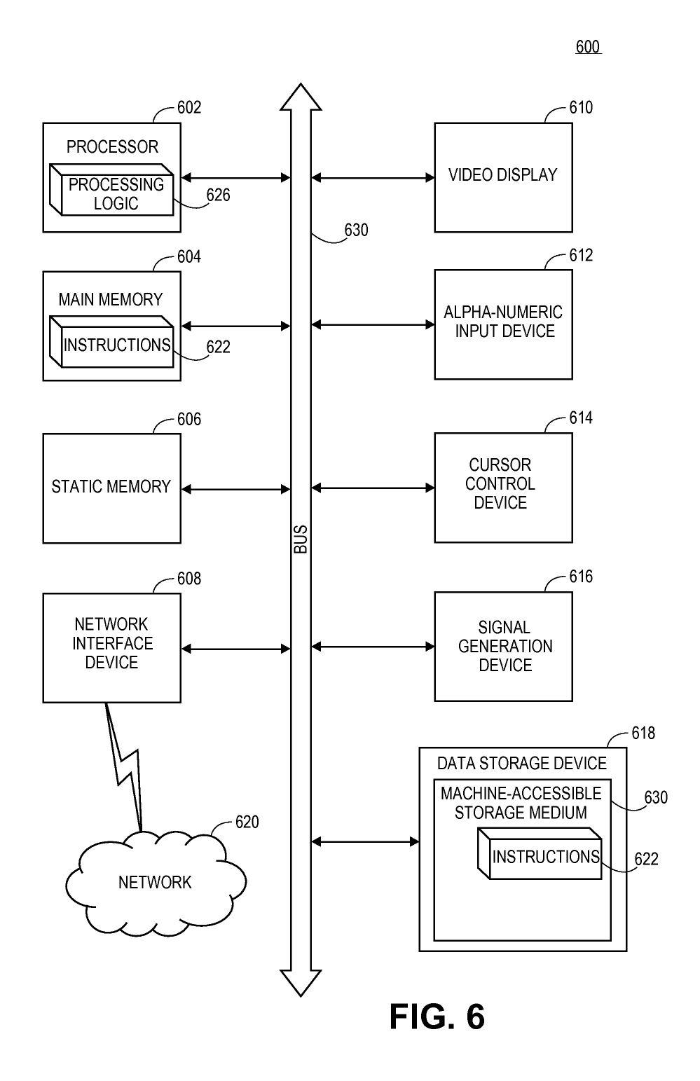

FIG. 6 shows a block diagram of an embodiment of a data processing system 600 to control the plasma system to recess an ULK dielectric as described herein. Data processing system processing 600 can represent a controller system 131 depicted in FIG. 1. In at least some embodiments, the data processing system 600 controls the plasma system 100 to perform operations involving modifying a portion of the ultra-low k dielectric layer over a substrate using a downstream plasma comprising a first chemistry; etching the modified portion of the ultra-low k dielectric over the substrate using the downstream plasma comprising a second chemistry, and sublimating the ultra-low k dielectric to remove by-products of etching, as described herein.

In alternative embodiments, the data processing system may be connected (e.g., networked) to other machines in a Local Area Network (LAN), an intranet, an extranet, or the Internet. The data processing system may operate in the capacity of a server or a client machine in a client-server network environment, or as a peer machine in a peer-to-peer (or distributed) network environment.

The data processing system may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that data processing system. Further, while only a single data processing system is illustrated, the term “data processing system” shall also be taken to include any collection of data processing systems that individually or jointly execute a set (or multiple sets) of instructions to perform any one or more of the methodologies described herein.

The exemplary data processing system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), a cathode ray tube (CRT), etc.), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 630 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 630 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In the foregoing specification, embodiments of the invention have been described with reference to specific exemplary embodiments thereof. It will be evident that various modifications may be made thereto without departing from the broader spirit and scope of embodiments of the invention as set forth in the following claims. The specification and drawings are, accordingly, to be regarded in an illustrative sense rather than a restrictive sense.

What is claimed is:

1. A method to manufacture an electronic device comprising:
modifying a portion of the ultra-low k dielectric layer over a substrate using a downstream plasma comprising a first chemistry; and
etching the modified portion of the ultra-low k dielectric layer using the downstream plasma comprising a second chemistry, wherein the downstream plasma is generated using a remote plasma source.

2. The method of claim 1, further comprising
sublimating the ultra-low k dielectric layer to remove by-products of etching.

3. The method of claim 1, further comprising
supplying a gas comprising the first chemistry to the remote plasma source; and
supplying a gas comprising the second chemistry to the remote plasma source.

4. The method of claim 1, wherein the first chemistry is argon, helium, other inert gas, nitrogen, hydrogen or any combination thereof.

5. The method of claim 1, wherein the second chemistry is nitrogen fluoride, ammonia, hydrogen, or any combination thereof.

6. The method of claim 1, further comprising
adjusting a first set of parameters to control modifying, wherein the first set of parameters comprises a pressure, a time duration, a power, a temperature, a gas flow, or any combination thereof.

7. The method of claim 1, wherein the downstream plasma is a substantially ion-free plasma, and wherein the ultra-low k dielectric layer has a dielectric constant K not greater than 2.2.

8. A method to recess an ultra-low k dielectric layer, comprising:
modifying a portion of an ultra-low k dielectric layer between portions of a conductive layer over a substrate using a downstream plasma comprising a first chemistry;
etching the modified portion of the ultra-low k dielectric layer using the downstream plasma comprising a second chemistry; and
sublimating the ultra-low k dielectric layer to remove by-products of etching.

9. The method of claim 8, wherein the modifying is performed at a bias power less or equal to 100 W, and wherein the modifying, etching and sublimating are continuously repeated until the ultra-low k dielectric layer is etched to a predetermined depth.

10. The method of claim 8, wherein a protection oxide layer is deposited on the ultra-low k dielectric layer.

11. The method of claim 8, wherein the first chemistry is argon, helium, other inert gas, nitrogen, hydrogen or any combination thereof.

12. The method of claim 8, wherein the second chemistry is nitrogen fluoride, ammonia, hydrogen, or any combination thereof.

13. The method of claim 8, wherein at least one of the modifying and etching is controlled by adjusting a time duration, a power, a pressure, a temperature, a gas flow, or any combination thereof.

14. The method of claim 8, wherein the sublimating is performed by
heating the ultra-low k dielectric layer.

15. An apparatus to recess an ultra-low k dielectric layer to manufacture an electronic device comprising:
a pedestal to hold a workpiece comprising an ultra-low k dielectric layer over a substrate;
an inlet to input a gas comprising one of a first chemistry and a second chemistry to provide to the workpiece;
a remote plasma source coupled to the inlet, the remote plasma source comprising a blocker plate to generate a substantially ion-free downstream plasma, wherein the blocker plate is to prevent ions of the plasma to reach the workpiece; and
a processor coupled to the remote plasma source, wherein the processor has a first configuration to control modifying a portion of the ultra-low k dielectric layer using the downstream plasma comprising the first chemistry, and wherein the processor has a second configuration to control etching of the modified portion of the ultra-low k dielectric layer using the substantially ion-free downstream plasma comprising the second chemistry.

16. The apparatus of claim 15, wherein the processor has a third configuration to control sublimating the ultra-low k dielectric layer to remove by-products of etching.

17. The apparatus of claim 16, wherein the processor has a fourth configuration to maintain a bias power less or equal to 100 W, and wherein the processor has a fifth configuration to continuously repeat the modifying, etching, and sublimating until the ultra-low k dielectric layer is etched to a predetermined depth.

18. The apparatus of claim 15, wherein the first chemistry is argon, helium, other inert gas, nitrogen, hydrogen or any combination thereof.

19. The apparatus of claim 15, wherein the second chemistry is nitrogen fluoride, ammonia, hydrogen, or any combination thereof.

20. The apparatus of claim 15, further comprising a memory coupled to the processor to store a first set of parameters to control the modifying, and to store a second set of parameters to control the etching.
